(19) United States
(12) Patent Application Publication
(10) Pub. No.: US 2010/0219989 A1
(43) Pub. Date: Sep. 2, 2010

(54) Input system and wearable electrical apparatus

(75) Inventors: Katsushi Asami, Nukata-gun (JP); Ichiro Akahori, Toyota-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/656,662

(22) Filed: Feb. 12, 2010

(30) Foreign Application Priority Data
Feb. 27, 2009 (JP) 2009-46635

(51) Int. Cl. H03K 17/94

(52) U.S. Cl. 341/20

(57) ABSTRACT

A wearable input device is worn on a finger of a user to detect contact and separation of the finger to and from the other body part of the user, respectively, and further measure motion of the finger. In the wearable input device, a signal supply unit supplies an electrical signal to a pair of signal electrodes worn on the finger, and a current sensor detects a current flowing between the signal electrodes. The contact and the separation are detected based on the detected current. Further a triaxial acceleration sensor detects the motion of the finger. A user input is determined by extracting only the trajectory of the motion of the finger detected when the finger is in contact with the other body part.

### CROSS REFERENCE TO RELATED APPLICATION

This application is based on and incorporates herein by reference Japanese Patent Application No. 2009-46636 filed on Feb. 27, 2009.

### FIELD OF THE INVENTION

The present invention relates to an input system and a wearable electrical apparatus used in the input system.

### BACKGROUND OF THE INVENTION

In one conventional input system, characters, figures or the like are inputted into a subject operation device such as an information processing unit, which is a subject device to be operated. The characters, figures or the like are inputted into the subject operation device by specifying coordinates on a touch panel or a tablet, on which a user expresses characters, figures or the like by using a stylus pen.

In another conventional input system (patent document 1), an electrical signal is applied to a contact face between a touch panel and a user so that the electrical signal also flows in a body of the user, when the user touches the contact face. The user touching the touch panel is specified based on the electrical signal, which flows in a body of the user when the user touches a contact surface.

In a further conventional input system using a human body (patent document 2), electromagnetic information generated by a user operation (tap operation) is generated and specify operation of the user based on the electromagnetic information so that input information corresponding to the user operation is generated.

In a still further conventional input system (patent document 3), a trajectory or path of movement of a finger of a user is measured so that characters expressed by a user may be recognized based on the movement trajectory. In a still further conventional input system (patent document 4), a touch pad or a tact switch is provided on a ring worn on a forefinger so that a user may operate it by his/her thumb.

Patent document 1: JP 2000-148396A

Patent document 2: JP 2008-197801A

Patent document 3: JP (PCT) 2006-500680A (US 2006/0149737A)

Patent document 4: JP 2006-302204A

However, according to the conventional input system, which uses the touch panel or the tablet, the touch panel or the tablet is required to have a sufficiently large area to express characters and figures thereon. Although the'touch panel or the tablet can be reduced in size if a fine-pointed stylus pen capable of expressing fine characters and figures is used. The stylus pen may be lost in some instances and therefore not advantageous.

In the conventional input system, which detects the tap operation of a user to generate input information into the subject operation device, characters or figures cannot be used to input information.

In addition, in the conventional input system, in which the touch pad or the tact switch is provided on the ring to be operated by the user with his/her thumb, the user is required to move finely and accurately the thumb to operate the touch pad or the tact switch. Further, this input system is not suited to input characters and figures.

In the conventional input system, which detects the trajectory of movement of the user's finger to recognize characters or figures, it is hard to accurately recognize characters, which cannot be completed in one continuous pen motion. That is, in this conventional input system, it cannot be determined whether the user is moving his/her finger with the pen in contact with or out of contact of a paper surface. As a result, it becomes more and more difficult to accurately recognize characters or figures as the characters or figures become more complicated.

### SUMMARY OF THE INVENTION

It is therefore an object of the present invention to provide an input system and an electrical apparatus for the input system, which can recognize characters or figures accurately without requiring touch panels nor tablets for receiving inputs of characters or figures.

According to one aspect of the present invention, an input system comprises a trajectory measurement section, a detection, section, a contact trajectory acquisition section and an input information generation section. The trajectory measurement section is configured to measure a trajectory of movement of a specified body part of a user. The detection section is configured to detect a contact and a separation of the specified body part to and from another body part of the user different from the specified body part by body motion of the user, respectively. The contact trajectory acquisition section is configured to acquire trajectory information indicating the trajectory of movement of the specified body part measured by the trajectory measurement section while the specified body part is detected by the detection section as being in contact with the another body part of the user. The input information generation section is configured to generate input information for a subject operation device based on the trajectory information acquired by the contact trajectory acquisition section.

According to another aspect of the present invention, an electrical apparatus wearable on a body of a user comprises a motion measurement section, a detection section and an output section. The motion measurement section is configured to measure a physical parameter value corresponding to trajectory of movement of a specified body part of the user. The detection section is configured to detect a contact and a separation of the specified body part to and from another body part of the user by body motion of the user, respectively. The output section configured to output the physical parameter value measured by the motion measurement section each time in correlation with a detection result of the detection section of the each time.

### BRIEF DESCRIPTION OF THE DRAWINGS

The above and other objects, features and advantages of the present invention will become more apparent from the following detailed description made with reference to the accompanying drawings. In the drawings:

FIG. 1A is a perspective view showing a first wearable input device 30, according to a first embodiment of the present invention;

FIG. 1B is a schematic view showing arrangement of electrodes and a current sensor of the first wearable input device;

FIG. 2A is a schematic sectional view of the first wearable input device;

FIG. 2B is another schematic sectional view of the first wearable input device;

FIG. 3A is a perspective view showing one exemplary use of the first wearable input device;

FIG. 3B is another perspective view showing another exemplary use of the first wearable input device;

FIG. 4A is a schematic view showing a case, in which the first wearable input device is used as an armlet;

FIG. 4B is another schematic view showing a case, in which the first wearable input device is used as an armlet;

FIG. 5A is a schematic view showing the principle of operation of the first wearable input device;

FIG. 5B is an equivalent circuit diagram showing current flow when the fingers are brought to contact as shown in FIG. 5A;

FIG. 6A is a block diagram of a remote control system, which uses the first wearable input device with an external device;

FIG. 6B is a circuit diagram showing a current sensor used in the first wearable input device;

FIG. 7A is a flowchart showing processing executed in the first wearable input device;

FIG. 7B is a waveform diagram showing example of data extraction executed in the processing of the first wearable input device;

FIG. 8 is a flowchart showing a first modification of the processing shown in FIG. 7A;

FIG. 9A is a flowchart showing a second modification of the processing shown in FIG. 7A;

FIG. 9B is a table showing relation between figure patterns and commands used in the processing shown in FIG. 9A;

FIG. 10A is a block diagram showing a second wearable input device according to a second embodiment of the present invention;

FIG. 10B is a schematic view showing arrangement of electrodes of the second wearable input device;

FIG. 11 is an equivalent circuit diagram of a measurement system of the second wearable input device;

FIG. 12A is a circuit diagram showing a third wearable input device according to a third embodiment of the present invention; and

FIG. 12B is a schematic view showing the principle of determination of whether fingers are in or out of contact with each other in the third wearable input device.

### DETAILED DESCRIPTION OF THE PREFERRED EMBODIMENTS

The present invention will be described in detail with reference to a number of embodiments shown in the accompanying drawings.

### First Embodiment

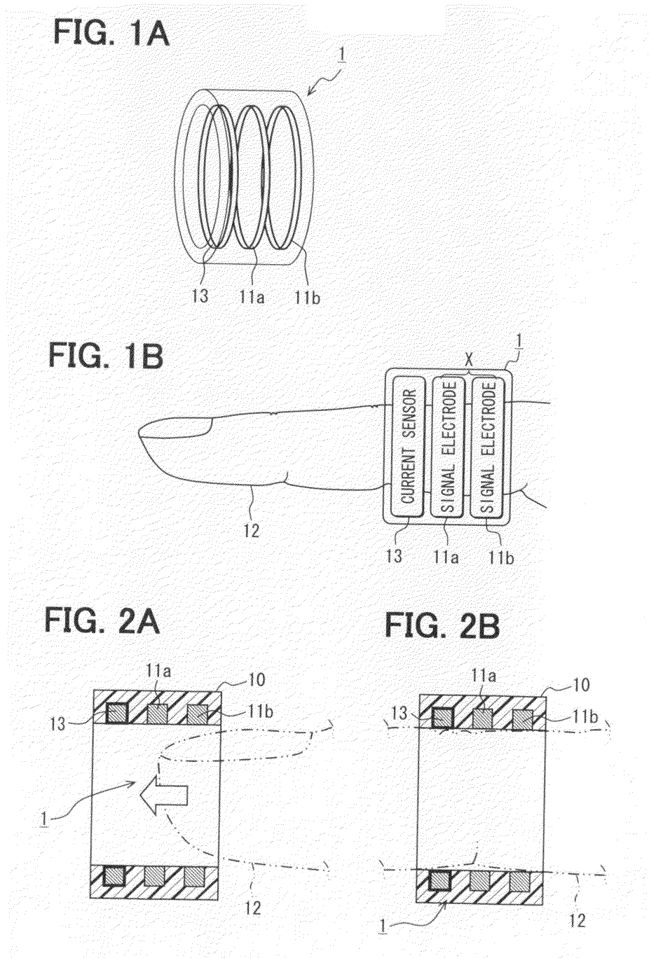

Referring to FIGS. 1A and 1B, a first wearable input device 1 includes a pair of signal electrodes 11a, 11b and a current sensor 13. Each signal electrode 11a, 11b is ring-shaped. The signal electrodes 11a, 11b and the current sensor 13 are arranged in parallel at predetermined intervals along the axial line of a user's finger 12. The current sensor 13 is provided outside the area X, which is sandwiched between the signal electrodes 11a, 11b.

The current sensor 13 is positioned between the signal electrodes 11a, 11b and the finger tip (nail part), that is, at the left side of the signal electrodes 11a, 11b. Instead, the current sensor 13 may be positioned between the signal electrodes 11a, 11b and the base of the finger, that is, at the right side (palm side) of the signal electrodes 11a, 11b. That is, when the first wearable input device 1 is used, the first wearable input device 1 can be worn in either orientation so that the current sensor 13 may be located outside the pair of signal electrodes 11a, 11b.

As shown in FIGS. 2A and 2B, the pair of signal electrodes 11a, 11b and the current sensor 13 are provided in a finger ring body 10 made of resin as an annular body, which forms the outer shape of the first wearable input device 1. They are integrated but electrically insulated from each other in the finger ring body 10. The signal electrodes 11a, 11b are housed in the finger ring body 10 with their inner surfaces facing inward of the ring being exposed from the finger ring body 10. Thus, when the first wearable input device 1 is worn on the finger 12, the signal electrodes 11a, 11b are brought into contact with the user's body surface (finger skin surface).

The current sensor 13 is so configured that, when a voltage is applied to the signal electrodes 11a, 11b as an electrical signal, the current flowing in the direction of the axis of a body site (finger) where the first wearable input device 1 is worn is measured by utilizing a magnetic field (magnetic flux) produced by a current, which flows in the direction of the axis of the body site (part).

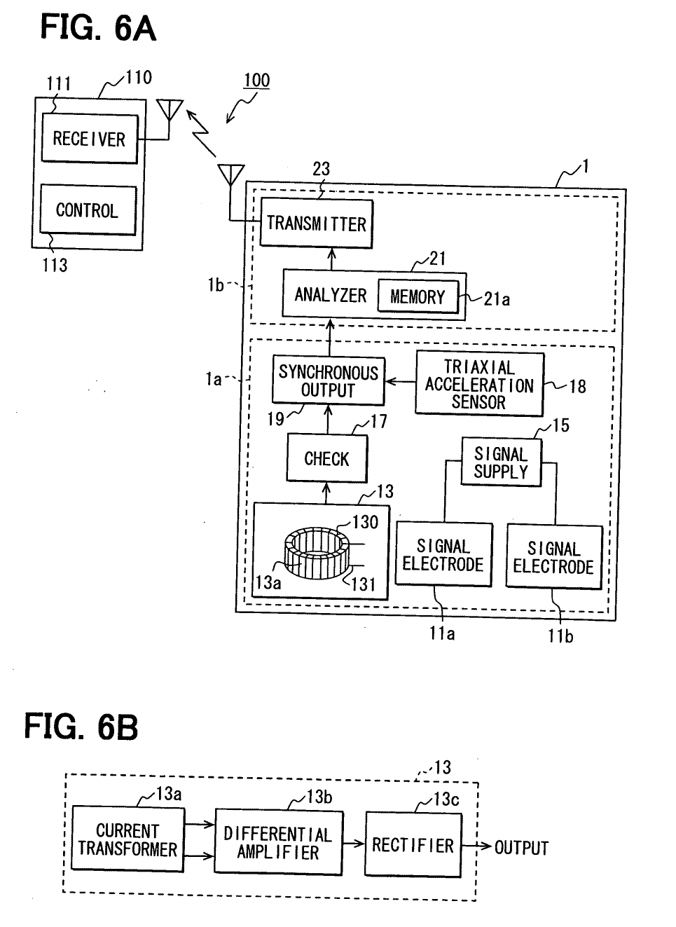

As shown in detail in FIG. 6A, the current sensor 13 includes a current transformer 13a, in which a coil 131 is wound on a core 130. The current sensor 13 measures the current flowing in the direction of the axis of the body site (finger) encircled with the current transformer 13a based on a voltage produced between the ends of the coil 131 of the current transformer 13a by electromagnetic induction.

The current sensor 13 is so configured as described above, because an alternating current (AC) voltage is applied to the signal electrodes 11a, 11b in the first wearable input device 1. However, a direct current (DC) voltage signal may be applied as the electrical signal between the signal electrodes 11a, 11b. In this case, the current sensor 13 may be formed of a Hall element. For example, the current sensor 13 can be configured as a sensor, in which a Hall element is placed in a cut formed in an annular core. The current, which flows in the direction of the axis of the body site (finger), can be measured by the Hall element based on a magnetic field produced between the ends of the core comprising the cut.

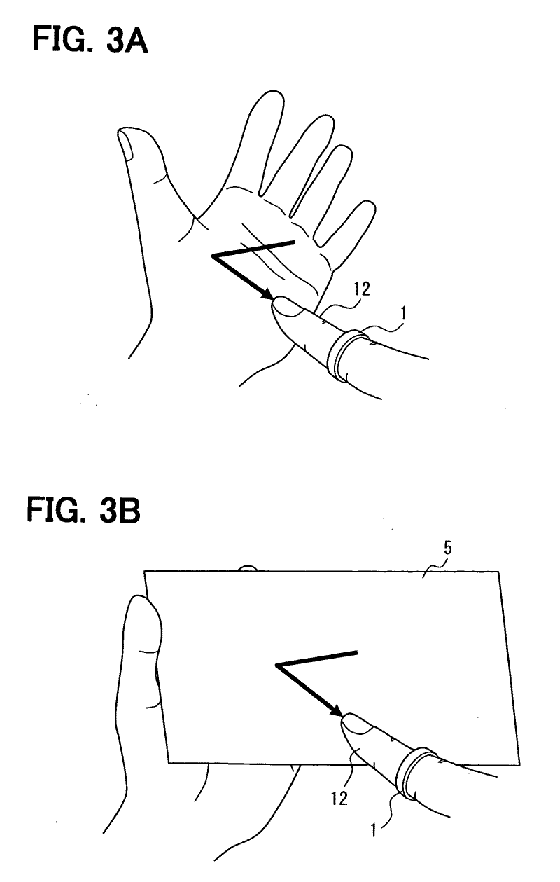

The principle of operation of the first wearable input device 1 is described with reference to FIGS. 3A and 3B.

The first wearable input device 1 is worn on a specified finger (for example, right hand forefinger) 12 and used to write characters or draw figures (including pictures, symbols, etc.) on a body part (for example, left hand palm) other than such a finger 12 as shown in FIG. 3A so that the trajectory of such a character or figure may be sensed by the first wearable input device 1. It is also possible, as shown in FIG. 3B, to hold a conductive plate 5 by the left hand and write a character or draw a figure on the conductive plate 5 in place of direct writing or drawing on the palm of the other hand. The finger, on which the first wearable input device 1 is worn, is referred to as an input finger.

Thus, the first wearable input device 1 has a function of measuring a trajectory of movement of the input finger, and a function of detecting contact or separation (non-contact or out-of-contact) of the top end of the input finger to and from the other body part of the user different from the input finger, respectively. With these functions, the trajectories of characters or figures, which the user expresses on a body part such as a palm are specified.

More specifically, for this operation, the alternating current signal is applied to the signal electrodes 11a, 11b of the first wearable input device 1 to detect whether the top end of the input finger of the user is in contact with or out of contact with the other body part of the user.

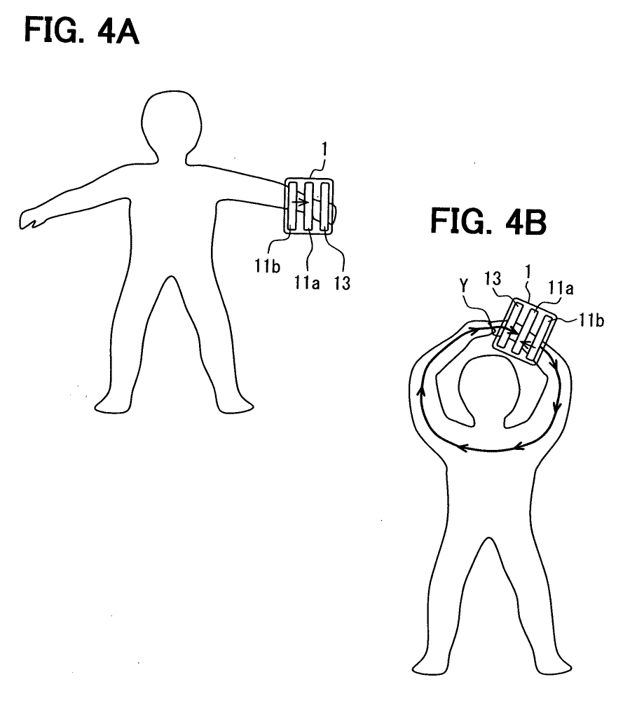

When the input finger and the other body part are separated and out of contact with each other (FIG. 4A), even when the signal is applied between the signal electrodes 11a, 11b, the supplied signal basically flows only through the body site (area X) sandwiched between the signal electrodes 11a, 11b, for example, from the signal electrode 11b to the signal electrode 11a. The current sensor 13 does not detect any current flowing therethrough and the measured current value is zero.

When the input finger and the other body part (for example, the other hand) are in contact with each other (FIG. 4B), a closed annular conduction path is formed through both hands, both arms and the main body of the user. In this case, the current sensor 13 is electrically sandwiched between the signal electrodes 11a, 11b through a point of contact Y formed between both hands in the clockwise direction in FIG. 4B. As a result, the supplied signal also flows through the current sensor 13 and the measured current value (effective value) of the current sensor 13 becomes larger than zero.

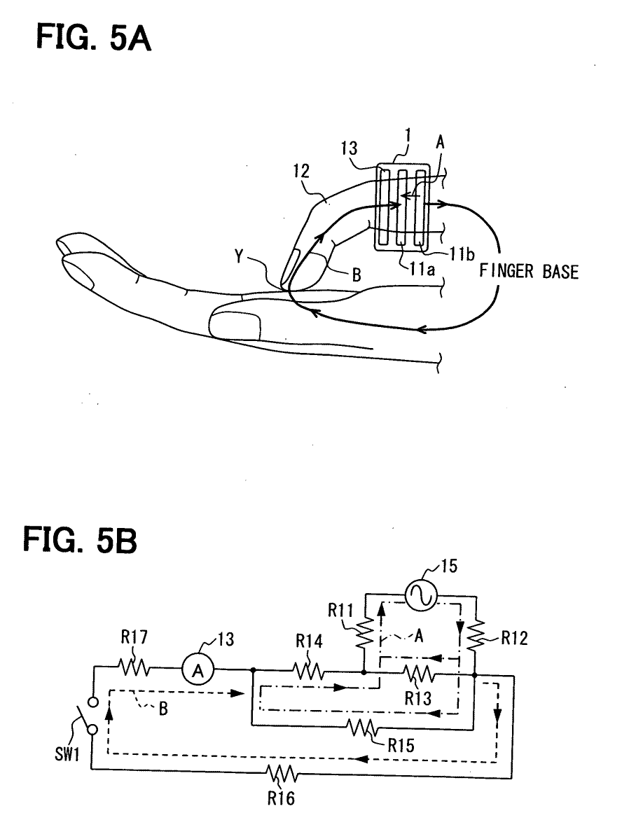

For example, when the user brings the input finger (right forefinger 12) wearing the first wearable input device 1 into contact with the palm of the other hand at point Y as shown in FIG. 5A, a first closed conduction path is formed from the signal electrode 11b to the signal electrode 11a through the right arm, main body, left arm and left palm of the user (not shown). It is noted that, whether the input finger is in contact or not with the palm of the other hand, a second closed conduction path is formed from the signal electrode 11b to the signal electrodes 11a through the area X.

Thus, when the forefinger of the right hand contacts the palm of the left hand, the signal supplied to the signal electrode 11b flows to the signal electrode 11a not only in the counter-clockwise direction but also in the clockwise direction. The current sensor 13 detects this current flowing in the clockwise direction. As a result, it is detected based on the current measured by the current sensor 13 whether the input finger in moved to contact with or separate from the other body part of the user.

FIG. 5B is an equivalent circuit diagram of the measurement system of the first wearable input device 1. The resistance of a body site, through which the alternating current signal applied to the signal electrodes 11a, 11b flows, is expressed by a lumped parameter system for the sake of simplicity of explanation.

Resistance R11 indicated in FIG. 5B represents the contact resistance between the signal electrode 11a and the input finger. Resistance R12 represents the contact resistance between the signal electrode 11b and the input finger. Resistance R13 represents the electrical resistance of the surface of the body site corresponding to the area X (FIG. 1) sandwiched between the signal electrodes 11a, 11b. Resistance R14 represents the electrical resistance of the surface of the body site extended from the measurement point of the current sensor 13 to the signal electrode 11a.

Resistance R15 represents the electrical resistance of the flow path (body's interior) of an electrical signal that flows through the body's interior between the signal electrode 11a and the current sensor 13 and is propagated between the signal electrodes 11a, 11b.

Resistance R16 represents the electrical resistance of a body site extended from the signal electrode 11b on the input finger 12 to the palm of the left hand in a case that the input finger 12 of the right hand is in contact with the palm of the left hand of the user as shown in FIG. 5A. Resistance R17 represents the electrical resistance of a body site extended from the top end of the input finger to the measurement point of the current sensor 13. A switch SW1 represents a condition at the point Y between the input finger and the palm of the left hand, that is, the input finger and the left hand palm are in (ON) or out of (OFF) contact with each other. The current sensor 13 is indicated as an ammeter.

The alternate long and short dash line in FIG. 5B indicates the flow of an electrical signal A, which flows only in the area X between the signal electrodes 11a, 11b regardless of whether the input finger of one hand and the palm of the other hand are in or out of contact with each other. The broken line indicates the flow of an electrical signal B, which flows between the signal electrodes 11a, 11b when the input finger of one hand and the palm of the other hand are in contact with each other (switch SW1 is in ON state). The flow direction of the signal B in the first conduction path is opposite to that of the signal A in the second conduction path.

When the first wearable input device 1 is worn on the forefinger and the forefinger is brought into or out of contact with the palm of the other hand, the mode of flow of electrical signals changes as described above. The measured value of current detected at the current sensor 13 is also varied. The first wearable input device 1 in this embodiment detects that fingers are brought into or out of contact with each other by a user's body movement based on measurement values varying as described above.

The top end of a forefinger with the first wearable input device 1 worn thereon may be brought into or out of contact with different body parts of the user other than the palm of the other hand. The top end of the forefinger with the first wearable input device 1 worn thereon may be brought into contact with the arm of the other hand of the user. Even when such body movement is carried out, the similar current change occurs in proximity to the current sensor 13. It is thus detected whether two body sites are in or out of contact with each other.

That is, the user can utilize the first wearable input device 1 to provide a signal indicating his/her motion to an external side by bringing a body site outside (finger tip side) of a body site where the first wearable input device 1 is worn into or out of any other body site.

For example, the first wearable input device 1 may be provided as a part of a remote operation system 100 as shown in FIG. 6A.

The first wearable input device 1 includes, in addition to the pair of signal electrodes 11a, 11b and the current sensor 13, a signal supply unit 15, a check unit 17, a triaxial acceleration sensor 18, a synchronous output unit 19, an analyzer unit 21 and a radio transmitter unit 23.

The signal supply unit 15 applies the alternating current signal (alternating current voltage) to the body site sandwiched between the signal electrodes 11a, 11b and is driven by a constant voltage or a constant current. The supplied signal may be a triangular wave signal, a sine wave signal, a rectangular wave signal, a sawtooth wave signal or the like.

The current sensor 13 measures the current flowing in the direction of the axis of the body site (finger) encircled with the annular current transformer 13a and inputs the resulting measured current value to the check unit 17.

In addition to the current transformer 13a, as shown in FIG. 6B, the current sensor 13 includes a differential amplifier circuit 13b and a rectifier 13c. The differential amplifier circuit 13b is connected to both ends of the coil 131 of the current transformer 13a, amplifies the difference between signals inputted from both ends of the coil 131, and outputs a resulting amplified signal. The rectifier 13c rectifies the output signal (alternating current signal) of the differential amplifier circuit 13b and converts it into a direct current signal. The current sensor 13 thus outputs an output signal from the rectifier 13c as a measured current value.

The effective value of voltage produced across the coil 131 of the current transformer 13a is converted into the measured value and outputted from the current sensor 13. This measured value (effective value) indicates a current flowing in the direction of the axis of the body site on which the current transformer 13a is worn.

In the current sensor 13, the difference between signals inputted from both ends of the coil 131 is amplified by the differential amplifier circuit 13b. Therefore, common mode noise inputted from both ends of the coil 131 can be cut out. However, it is also possible to provide a filter between the differential amplifier circuit 13b and the rectifier circuit 13c for passing only signals of the same frequency as that of signals applied between the signal electrodes 11a, 11b. Thus the current sensor 13 can remove noise that cannot be removed even by the differential amplifier circuit 13b. It is also possible to configure the current sensor 13 so that synchronous wave-detection may be performed by using the signal supplied from the signal supply unit 15 as a reference signal.

The check unit 17 checks whether the input finger is in contact with or out of contact from the other body part based on the measured current value inputted from the current sensor 13.

Specifically the check unit 17 compares the measured current value inputted from the current sensor 13 with a predetermined threshold value. If the measured current value is greater than the predetermined threshold value, the check unit 17 determines that the input finger is in contact with the other body part of the user and outputs a condition determination value indicating the contact of the input finger to the synchronous output unit 19. If the measured current value is equal to or less than the predetermined threshold value, the check unit 17 determines that the input finger is out of contact from the other body part of the user and output a condition determination value indicating non-contact or separation of the input finger to the synchronous output unit 19.

The triaxial acceleration sensor 18 is configured to detect motion of the input finger by detecting acceleration generated therein in the x, y, z axes, which are orthogonal one another, and output the triaxial components (x, y, z axis components) of the detected acceleration as an acceleration measurement value. This acceleration measurement value is outputted to the synchronous output unit 19. The triaxial acceleration sensor 18 inputs into the synchronous output unit 19 the triaxial components of the acceleration of the input finger in response to the movement of the input finger.

The synchronous output unit 19 is configured to input the measurement data into the analyzer unit 21. The measurement data includes the acceleration measurement value and the condition determination value at each time. The acceleration measurement value inputted from the triaxial acceleration sensor 18 at each time is correlated to the determination result (condition determination value) of the check unit 17, which corresponds to the current measurement value measured at the same time.

The analyzer unit 21 is configured to time-sequentially store in its built-in memory 21a the measurement data (data including the acceleration measurement value and the condition determination value) produced from the synchronous output unit 19 and specify a character or a figure, which the user expressed, based on the group of measurement data stored in the memory 21a indicating the trajectory of the input finger.

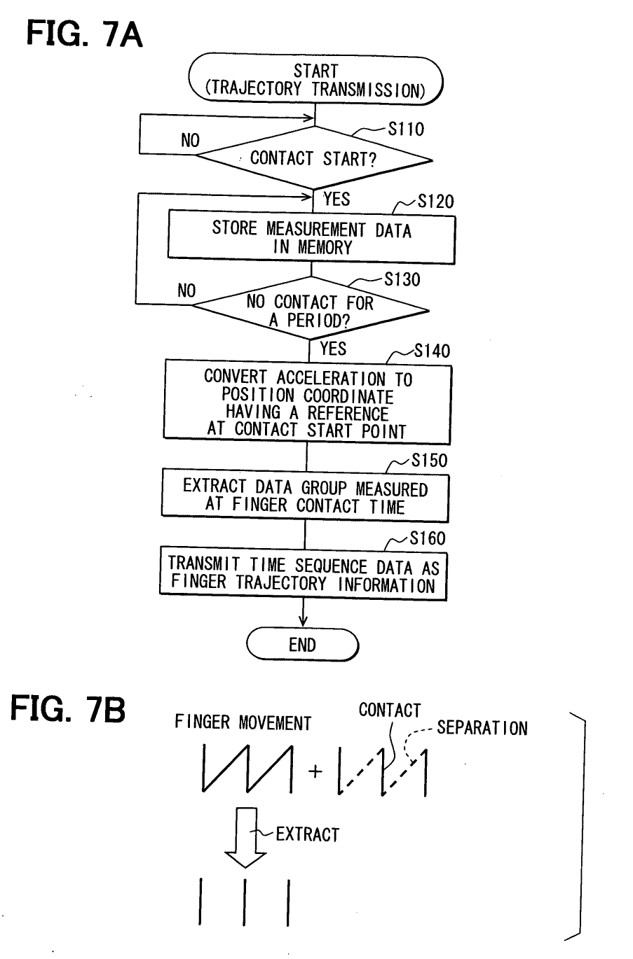

The analyzer unit 21 is configured to execute trajectory transmission processing shown in FIG. 7A.

In this processing, the analyzer unit 21 first checks at S110 whether the input finger is started to contact the other body part based on the measurement data inputted from the synchronous output unit 19.

S110 is repeated until the condition determination value indicated by the latest measurement data changes from a condition determination value indicating that the input finger is separated from and not in contact with the other body part to a condition determination value indicating that the input finger is in contact with the other body part.

If the contact is started (Yes at S110), the analyzer unit 21 stores the measurement data inputted from the synchronous output unit 19 in the built-in memory unit 21a at S120. This data storing processing is repeated until it is determined at S130 that the input finger is separated from the other body part for a predetermined period.

If input of the condition determination value indicating that the input finger is separated continues for more than the predetermined period (Yes at S130), the analyzer unit 21 determines that the input finger is not in contact with the other body part any more.

At S140, the analyzer unit 21 converts the acceleration measurement values indicated by a series of measurement data stored in the memory 21a into a position coordinate having a reference (point of origin) at a position, at which the input finger is placed when the contact is started. The measurement data is acquired after the input finger is started to contact until it is separated for the predetermined period.

More specifically, the acceleration measurement value at each time is converted into the position coordinate of the input finger of each time by integrating two times in the time direction the acceleration measurement value (triaxial components of acceleration) indicated by the measurement data of each time stored in the memory 21a.

After this processing, the analyzer unit 21 extracts a measurement data group, which includes the condition determination value indicating the contact of the input finger, from measurement data group acquired during a period from the start of contact and the continued separation of the input finger. The data of the measurement data group is acquired by conversion of the acceleration measurement value stored in the memory 21a into the position coordinate.

Thus, at S150, the measurement data group indicating the position coordinate of the input finger while the input finger is in contact with the other body part. This extraction operation is shown in FIG. 7B, in which an example of movement of the input finger detected by the triaxial acceleration sensor 18 is shown at the upper top part, the contact (solid line) and non-contact (dotted line) of the input finger determined by the check part 27 are shown at the upper right part, and the extracted trajectory of the input finger moved in contact with the other body part is shown at the bottom left part.

At S160 following S150, only the position coordinate is extracted from each measurement data extracted at S150 and a time-sequence data of the position coordinate indicated by each measurement data is generated. This time-sequence data of the position coordinate is transmitted to an external device 110 through the radio transmitter unit 23. The external device 110 is a subject operation device in this embodiment.

The analyzer unit 21 thus supplies the external device 110 with the trajectory data (time-sequence data of the position coordinate) of characters or figures, which the user expressed by the input finger on the other body part, through the radio transmitter unit 23. The external device 110 includes a radio receiver unit 111 and a control unit 113. The radio receiver unit 111 receives the data transmitted in the form of radio wave from the first wearable unit 1. The control unit 113 executes processing using the received data. For example, the external device 110 executes processing of displaying characters or figures expressed by the user on a display screen based on the time-sequence data of the position coordinate inputted from the first wearable input device 1.

According to the first embodiment, a user can fit his/her finger into the first wearable input device 1 and input characters or figures to the external device 110 by just expressing such characters or figures by moving such a finger on and in contact with his/her other body part such as a palm of his/her hand.

Therefore, no tablet or stylus pen is required. Characters or figures can be inputted into the external device 110 by a small-sized device.

Further by not only measuring the trajectory of movement of the input finger but also detecting the contact or non-contact of the input finger with the other body part, the trajectory of a character or figure expressed by a user can be acquired by detecting a user's motion, which corresponds to contacting or separating a pen to and from a paper.

The user can thus readily input a character or figure into the external device 110 even if such a character or figure is a combination of a plurality of discontinuous strokes. That is, the data of trajectory of a character or figure can be inputted to the external device 110 so that such a character or figure, which the user expresses, can be recognized by the external device 110 or by other users accurately.

Thus, this input device is suited to input characters or figures and very versatile. The first wearable input device 1 need not be configured as a single unit but may be configured as a combination of a plurality of element parts. For example, as indicated in FIG. 6A, it may be divided into two function parts, that is, a measurement data output part 1a and an input data generation part 1b, which processes the measurement data group and generates the input data to be transmitted to the external device 110. That is, the first wearable input device 1 may be separated into a first device including the function part 1a and a second device including the function part 1b. In this case, the first wearable input device 1 may be configured such that the first device transmits the measurement data to the second device by way of radio communications.

The first wearable input device 1 need not be in a finger ring shape but may be enlarged in size as an arm ring or armlet as shown in FIGS. 4A and 4B. In this case, any fingers of a hand, on which the first wearable input device 1 is worn, can be used to as the input finger to express characters or figures.

It is noted that, in case of using the conductive plate held by the other hand different from the hand of the input finger as shown in FIG. 3B, the measuring system has the same equivalent circuit as that shown in FIG. 5.

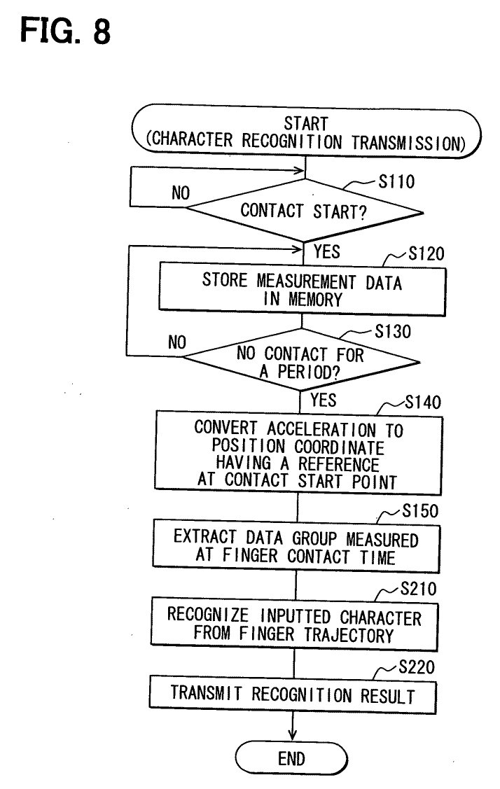

The analyzer unit 21 may be configured to execute character recognition and transmission processing as shown in FIG. 8 in place of the trajectory transmission processing shown in FIG. 7A. This processing is a first modification of the first embodiment.

The analyzer unit 21 executes S110 to S150, which are the same as those described with reference to FIG. 7A.

Following S150, the analyzer unit 21 recognizes at S210 a character, which the user expresses with the input finger, from the trajectory of the position coordinate indicated by the extracted measurement data group. A character may be recognized by evaluating the degree of agreement between the trajectory pattern of the position coordinate indicated by the measurement data group and a pre-stored trajectory pattern of a subject character.

After S210, the analyzer unit 21 transmits data indicating the character recognition result to the external device 110 through the radio transmitter unit 23 at S220.

Thus, information of the character expressed by the input finger is inputted into the external device 110 in the first modification.

As data representing the recognition result of the character, data representing the recognized character can be inputted to the external device 110. If the character cannot be successfully recognized, data indicating failure in the character recognition may be transmitted to the external device 110 as the data representing the character recognition result. Alternatively, if the character recognition is not successful, no data may be transmitted to the external device 110.

Thus, the first wearable input device 1 may be used as an input device for inputting characters into the external device 110 by configuring the analyzer unit 21 to execute the above-described character recognition and transmission processing in place of the trajectory transmission processing shown in FIG. 7A.

Further, the user action corresponding to contacting or separating a pen to or from a paper can be detected and the trajectories of characters or figures expressed by the user, by detecting the contact and non-contact of the input finger with the other body part. As a result, characters or figures inputted by the input finger of the user can be recognized more accurately than in the conventional device, which recognizes characters based on single stroke writing.

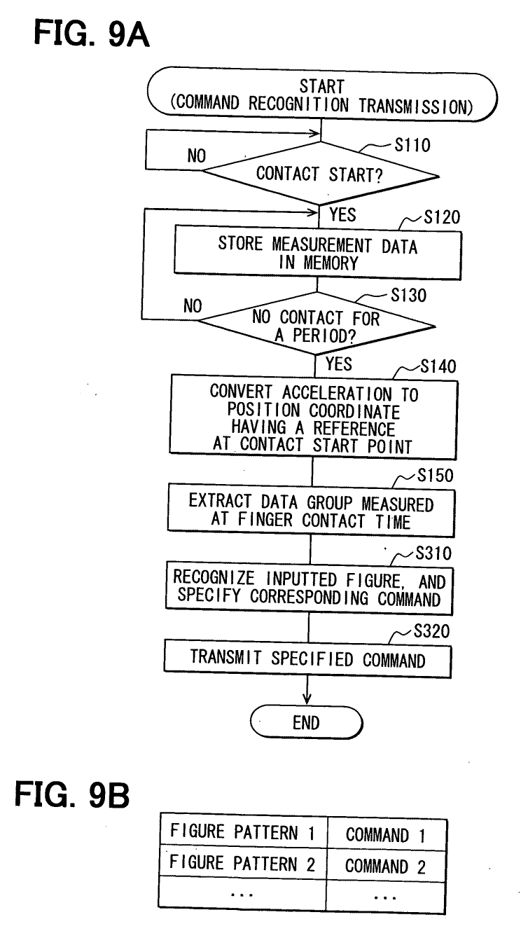

The analyzer unit 21 may be configured to execute command recognition and transmission processing shown in FIG. 9A in place of the trajectory transmission processing shown in FIG. 7A and the character recognition and transmission processing shown in FIG. 8. This processing is a second modification of the first embodiment.

The analyzer unit 21 executes S110 to S150, which are the same as those described with reference to FIG. 7A.

Following S150, the analyzer unit 21 recognizes at S310 a figure inputted by the input finger of the user from the trajectory of the position coordinate indicated by the extracted measurement data group. The figure includes a character as well.

A figure may be recognized by evaluating the degree of agreement between the trajectory pattern of the position coordinate indicated by the measurement data group and a pre-stored trajectory pattern of a subject figure.

Following S310, the analyzer unit 21 specifies a command for the external device 110 corresponding to the recognized figure and generates input data indicating the specified command. Then, the analyzer unit 21 transmits the input data indicating the specified command to the external device 110 through the radio transmitter unit 23 at S320.

The analyzer unit 21 preferably pre-stores a concordance table representing a predetermined relation between figures and commands as shown in FIG. 9B so that the command may be specified in correspondence to the recognized figure by referring to the pre-stored concordance table at S310.

If the figure cannot be successfully recognized at S310, a predetermined command may be transmitted to the external device 110 through the radio transmitter unit 23. The predetermined command is prepared for a case of failure in recognition and may be a command for requesting the external device 110 to display a message, which requests another input of the figure. Alternatively, if the figure recognition is not successful, no command may be transmitted to the external device 110 through the radio transmitter unit 23.

Thus, information of the character expressed by the input finger is inputted into the external device 110 in the first modification. As data representing the recognition result of the character, data representing the recognized character can be inputted to the external device 110. According to the second modification, the first wearable input device 1 may be used as a remote controller for the external device 110.

Further, since the input figure can be recognized accurately, the external device 110 is effectively prevented from being operated unintentionally due to erroneous recognition of figures inputted by the input finger.

### Second Embodiment

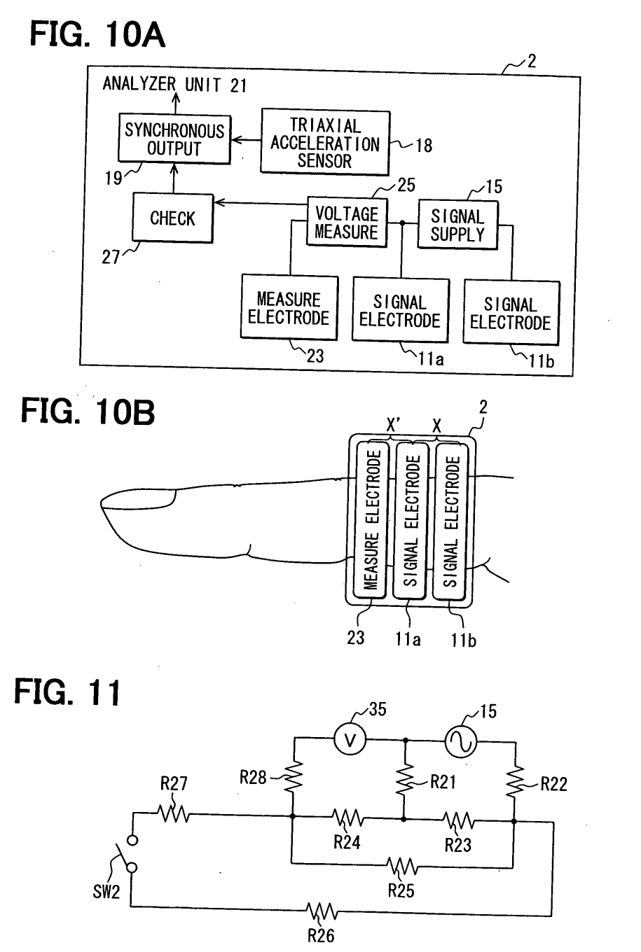

A second wearable input device 2 is shown in FIGS. 10A and 10B as a second embodiment.

The second wearable input device 2 is different from the first wearable input device 1 only in that voltage measurement is carried out instead of the current measurement. With respect to the second wearable input device 2, therefore, the same constituent elements as in the first embodiment will be denoted with the same reference numerals and the description thereof will be simplified.

As shown in FIGS. 10A and 10B, the second wearable input device 2 includes, in addition to the pair of signal electrodes 11a, 11b, a measurement electrode 23 similarly formed in a ring-shape. These electrodes 11a, 11b, 23 are arranged in parallel at predetermined intervals along the axial line of the finger. Thus, the second wearable input device 2 includes the measurement electrode 23 in place of the current sensor 13.

Similarly to the current sensor 13, the measurement electrode 23 is provided so that it is positioned in an area outside the area X sandwiched between the signal electrodes 11a, 11b. Similarly to the signal electrodes 11a, 11b, the measurement electrode 23 is housed in the finger ring body 10 so that, when the second wearable input device 2 is worn on the finger, the inner surface facing inward of the ring is exposed from the finger ring body so that the measurement electrode 23 is also brought into contact with the user's body surface (finger surface).

The second wearable input device 2 further includes a voltage measurement unit 25 and a check unit 27 in addition to the signal supply unit 15, the triaxial acceleration sensor 18, the synchronous output unit 19 and the like. The alternating current signal is applied between the signal electrodes 11a, 11b by the signal supply unit 15 as in the first embodiment. Meanwhile, voltage (effective value) produced between the signal electrode 11a and the measurement electrode 23 is measured by the voltage measurement unit 25 and the resulting measured voltage value is inputted to the check unit 27.

The check unit 27 checks the finger condition based on the measured voltage value inputted from the voltage measurement unit 25. If the measured voltage value is higher than a predetermined threshold value, the check unit 27 determines that the input finger wearing the second wearable input device 2 is in contact with the body part of the user. If the measured voltage value is equal to or less than the predetermined threshold value, the check unit 27 determines that the input finger is out of contact. The check unit 27 outputs its check result to the synchronous output unit 19.

The synchronous output unit 19 outputs, as measurement data, the condition determination value inputted from the check unit 37 and the acceleration measurement value inputted from the triaxial acceleration sensor 18 by time-synchronizing the two input data. This measurement data is used by the analyzer unit 21 as described with reference to FIGS. 7A, 8 and 9A.

FIG. 11 is an equivalent circuit diagram of the measurement system in the second wearable input device 2. In FIG. 10B, resistance R21 represents the contact resistance between the signal electrode 11a and the finger. Resistance R22 represents the contact resistance between the signal electrode 11b and the finger. Resistance R28 represents the contact resistance between the measurement electrode 23 and the finger.

Resistance R23 represents the electrical resistance of the body site surface corresponding to the area X sandwiched between the signal electrodes 11a, 11b. Resistance R24 represents the electrical resistance of the body site surface corresponding to the area X′ (FIG. 10B) sandwiched between the signal electrode 11a and the measurement electrode 23. Resistance R25 represents the electrical resistance of the path through which the signal applied between the signal electrodes 11a, 11b flows through the body's interior and leaks out toward the measurement electrode 23.

It is assumed that the second wearable input device 2 is worn on the forefinger as the input finger and the forefinger and the palm of the other hand are brought into or out of contact with each other as exemplified in FIGS. 3A and 3B as in the first embodiment. In this case, resistance R26 represents the electrical resistance of the body site extended from the signal electrode 11b to the palm of the other hand of the user through the main body and both arms of the user. Resistance R27 represents the electrical resistance of the body site extended from the top end of the forefinger to the body site where the measurement electrode 23 is worn. The voltage measurement unit 25 may be a voltmeter.

As described above, the resistance R25 representing the electrical resistance of the current flow path, through which a signal applied between the signal electrodes 11a, 11b flows through the body's interior and leaks out toward the measurement electrode 23, is very large to any other body site, though this depends on the interval between the installed signal electrode 11a and measurement electrode 23. If the input finger is out of contact with the palm of the other hand of the user (switch SW2 is OFF), therefore, the measured voltage value Voff measured at and outputted from the voltage measurement unit 25 is close to zero. If the input finger of one of the hands and the palm of the other hand are in contact with each other (switch SW2 is ON), meanwhile, the signal flows through the resistances R26, R27, which are sufficiently smaller than the resistance R25. Therefore, the measured voltage value Von measured by and outputted from the voltage measurement unit 25 is sufficiently higher than the measured voltage value Voff.

Therefore, it can be determined whether or not the input finger is in contact with other body parts of the user by checking whether or not the measured voltage value inputted from the voltage measurement unit 25 is higher than the predetermined threshold value.

In this embodiment, the alternating current signal is applied from the signal supply unit 15 to the signal electrodes 11a, 11b as an example. Similarly to the first embodiment, however, a direct current signal may alternatively be applied from the signal supply unit 15.

It is also possible to provide a phase measurement unit in place of the voltage measurement unit 35, when the alternating signal is supplied from the signal supply unit 15. The phase measurement unit is configured to measure a phase delay of the alternating signal inputted from the measurement electrode 33 relative to the alternating signal supplied to the signal electrodes 11a, 11b based on the voltage (alternating signal) developed between the signal electrode 11a and the measurement electrode 33.

In this instance, it is determined that, if the measured phase delay value is greater than and less than a predetermined threshold value, the input finger is in contact with and out of contact from the palm of the other body part of the user, respectively.

### Third Embodiment

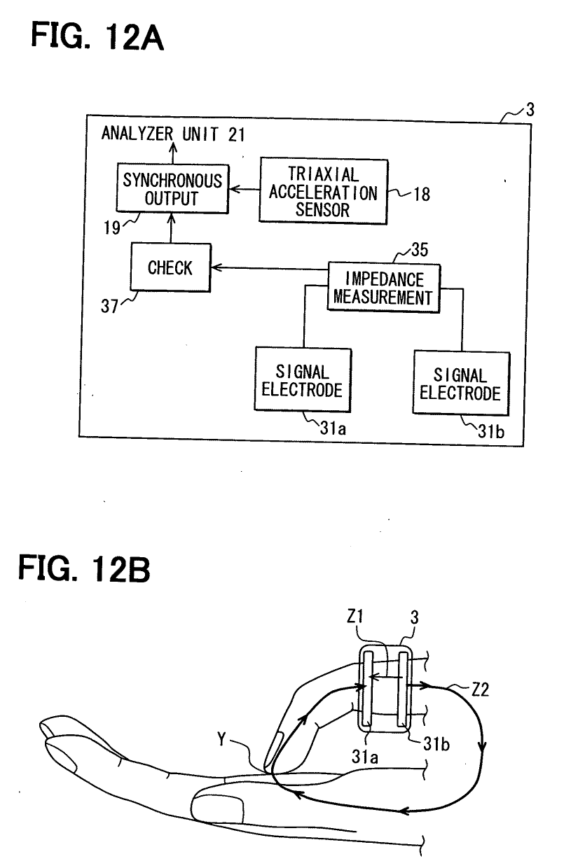

A third wearable input device 3 is shown in FIGS. 12A and 12B as a third embodiment.

The third wearable input device 3 includes ring-shaped signal electrodes 31a, 31b similar to the signal electrodes 11a, 11b and an impedance measurement unit 35 that measures impedance between the pair of ring-shaped signal electrodes 31a, 31b. A check unit 37 checks whether the input finger is in or out of contact based on the measured impedance value (absolute value) inputted from the impedance measurement unit 35 and outputs its check result to the synchronous output unit 19, so that the check result indicating the contact or non-contact of the input finger with the other body part of the user may be used in the same manner as in the first and the second embodiments.

In this third wearable input device 3, the impedance measurement unit 35 applies the alternating current signal between the ring-shaped signal electrodes 31a, 31b and measures a current arising therefrom to measure an impedance Z between the ring-shaped signal electrodes 31a, 31b.

The impedance Zon measured by the impedance measurement unit 35 when the input finger is in contact at point Y as shown in FIG. 12B is calculated as Zon=Z1×Z2/(Z1+Z2) using two impedances Z1 and Z2. The impedance Z1 is formed in the path between the ring-shaped signal electrodes 31a, 31b, through which the supplied signal flows through only a part of the input finger (for example, in the counterclockwise direction in FIG. 12B) and not by way of the point of contact Y. The impedance Z2 is formed in the path between the ring-shaped signal electrodes 31a, 31b through which the supplied signal flows by way of the point of contact Y between the signal electrodes 31a, 31b (for example, in the clockwise direction in FIG. 12B).

The impedance Zoff measured by the impedance measurement unit 35 when the input finger is out of contact from the other body part of the user is calculated as Zoff=Z1.

Therefore, an inequality of Zoff>Zon holds between the impedances Zoff and Zon. The impedance Zoff measured by the impedance measurement unit 35 is large, because no closed current conduction path is provided by way of the body part of the user. The impedance Zon measured by the impedance measurement unit 35 is small, because a closed current conduction path is provided by way of the body part including the contact point Y.

For the above reason, the check unit 37 makes determination as follows. If the measured impedance value Z inputted from the impedance measurement unit 35 is higher than a predetermined threshold value, it determines that the input finger is out of contact from the other body part of the user. If the measured impedance value Z is equal to or lower than the predetermined threshold value, it determines that the input finger is in contact with the other body part of the user.

According to the third wearable input device 3, contact and non-contact of the input finger with the other body part of the user can be detected as well. Further, the trajectories of characters or figures expressed on the palm or the like by the input finger of the user can be detected, even if each of the characters or figures is not a simple pen stroke but is a combination of a plurality of pen strokes.

The impedance may be measured by supplying a direct current voltage to the signal electrodes 31a, 31b in place of supplying the alternating current.

The present invention is not limited to the disclosed embodiments but may be implemented in different ways.

For example, the signal electrodes 11a, 11b and the signal supply unit 15 in the first wearable input device 1 are electrically separated from other constructional parts. Therefore, the first wearable input device 1 may be separated into a signal supply-side device, which includes the signal electrodes 11a, 11b and the signal supply unit 15, and a measurement-side device, which includes other electrical components.

In this example, the signal supply-side device may be worn on the forefinger of a right hand and the measurement-side device may be worn as an armlet so that the similar closed conduction path may be formed as shown in FIG. 5A. The user can write characters or draw figures on the palm of his/her left hand by the input forefinger of his/her right hand.

In each of the wearable input devices 1, 2, 3, the electrodes need not be shaped in the closed ring form. The electrodes may be shaped in an arc form or other forms.

It is preferred that the electrodes are sized large to contact the body of the user over a sufficient contact area so that the wearable input devices 1, 2, 3 may operate stably and accurately. The electrodes may be pressed to the body surface firmly by applying biasing force to the electrodes.

The wearable input devices 1, 2, 3 may be configured to output data to the external device 110 via wired communications in place of wireless communications.

In the above-described embodiments and modifications, the signal electrodes 11a, 11b, 31a, 31b and the signal supply unit 15 operate as a signal supply section. The current sensor 13 forms a signal measurement section. The check unit 17, 27, 37 operates as a detection section. The triaxial acceleration sensor 18 operates as a motion detection section and a trajectory measurement section. The synchronous output unit 19 operates as an output section. The analyzer unit 21 operates as the trajectory measurement section and a contact trajectory acquisition section. The current flowing between the signal electrodes 11a, 11b, the voltage between the signal electrode 11a and the measurement electrode 23 and the impedance between the signal electrodes 31a, 31b are measured by the current sensor 13, the voltage measurement unit 25 and the impedance measurement unit 35 as the physical parameter of the electrical signal, respectively.

What is claimed is:

1. An input system comprising:
a trajectory measurement section configured to measure a trajectory of movement of a specified body part of a user;
a detection section configured to detect a contact and a separation of the specified body part to and from an another body part of the user different from the specified body part by body motion of the user, respectively;
a contact trajectory acquisition section configured to acquire trajectory information indicating the trajectory of movement of the specified body part measured by the trajectory measurement section while the specified body part is detected by the detection section as being in contact with the another body part of the user; and
an input information generation section configured to generate input information for a subject operation device based on the trajectory information acquired by the contact trajectory acquisition section.

2. The input system according to claim 1, further comprising:
a signal supply section configured to supply an electrical signal to the specified body part of the user; and
a signal measurement section configured to measure a physical parameter value of the electrical signal, which flows in the body of the user,
wherein the detection section is configured to detect the contact and the separation of the specified body part based on the physical parameter value measured by the signal measurement section.

3. The input system according to claim 2, wherein:
the signal supply section includes a pair of signal electrodes adapted to be worn on a surface of the specified body part to form a closed conduction path only when the specified body part and the another body part of the user contact each other, the pair of signal electrodes being configured to supply an electrical signal in a body part sandwiched therebetween; and
the signal measurement section includes a detector element configured to be worn on the specified body part in parallel to the pair of signal electrodes and outside the pair of signal electrodes and detect the physical parameter value of the electrical signal flowing in the closed conduction path.

4. The input system according to claim 1, wherein:
the signal supply section includes a pair of signal electrodes adapted to be worn on a surface of the specified body part to form a closed conduction path only when the specified body part and the another body part of the user contact each other;
the signal measurement section includes an impedance measurement section configured to measure an impedance of a body part sandwiched between the pair of signal electrodes; and
the detection section is configured to detect the contact and the separation of the specified body part based on the impedance measured by the impedance measurement section.

5. The input system according to claim 1, wherein:
the contact trajectory acquisition section is configured to acquire the trajectory information by extracting, from a plurality of trajectories of movement measured by the trajectory measurement section, the trajectory of movement measured when the specified body part is detected as being in contact with the another body part.

6. The input system according to claim 1, wherein:
the input information generation section is configured to generate the input information based on the trajectory information, which is provided from detection of a start of the contact of the specified body part to the another body part until detection of continuation of the separation of the specified body part from the another body part for a predetermined time period.

7. The input system according to claim 1, wherein:
the input information generation section is configured to recognize a character expressed by the motion of the specified body part based on the trajectory information acquired by the contact trajectory acquisition section and generate recognized character information as the input information.

8. The input system according to claim 1, wherein:
the input information generation section is configured to recognize a figure pattern expressed by the motion of the specified body part based on the trajectory information acquired by the contact trajectory acquisition section and generate a command as the input information, the command being selected from a predetermined relation between predetermined figure patterns and commands.

9. An electrical apparatus wearable on a body of a user comprising:
a motion measurement section configured to measure a physical parameter value corresponding to trajectory of movement of a specified body part of the user;
a detection section configured to detect a contact and a separation of the specified body part to and from an another body part of the user by body motion of the user, respectively; and
an output section configured to output the physical parameter value measured by the motion measurement section each time in correlation with a detection result of the detection section of the each time.

10. The electrical apparatus according to claim 9, further comprising:
a signal supply section configured to supply an electrical signal to a body of the user; and
a signal measurement section configured to measure a physical parameter value of the electrical signal, which flows in the body of the user,
wherein the detection section is configured to detect the contact and the separation of the specified body part based on the physical parameter value measured by the signal measurement section.

11. The electrical apparatus according to claim 10, wherein:
the signal supply section includes a pair of signal electrodes adapted to be worn on a surface of the specified body part to form a closed conduction path only when the specified body part and another body part of the user contact each other, the pair of signal electrodes being configured to supply an electrical signal in a body part sandwiched therebetween; and
the signal measurement section includes a detector element configured to be worn on the specified body part in parallel to the pair of signal electrodes and outside the pair of signal electrodes and detect the physical parameter value of the electrical signal flowing in the closed conduction path.

12. The electrical apparatus according to claim 9, wherein:
the signal supply section includes a pair of signal electrodes adapted to be worn on a surface of the specified body part to form a closed conduction path only when the specified body part and the another body part of the user contact each other;
the signal measurement section includes an impedance measurement section configured to measure an impedance of a body part sandwiched between, the pair of signal electrodes; and
the detection section is configured to detect the contact and the separation of the specified body part based on the impedance measured by the impedance measurement section.
